(19) United States
(12) Patent Application Publication
(10) Pub. No.: US 2019/0214293 A1
(43) Pub. Date: Jul. 11, 2019

(54) SEMICONDUCTOR DEVICE INCLUDING INSULATING LAYERS AND METHOD OF MANUFACTURING THE SAME

(71) Applicant: Samsung Electronics Co., Ltd., Suwon-si (KR)

(72) Inventors: Kyu Jin Kim, Hwasung-si (KR); Min Su Choi, Hwasung-si (KR); Sung Hee Han, Hwasung-si (KR); Bong Soo Kim, Hwasung-si (KR); Yoo Sang Hwang, Hwasung-si (KR)

(73) Assignee: Samsung Electronics Co., Ltd., Suwon-si (KR)

(21) Appl. No.: 16/028,794

(22) Filed: Jul. 6, 2018

(30) Foreign Application Priority Data
Jan. 9, 2018 (KR) 10-2018-0002831

(51) Int. Cl. H01L 21/762; H01L 27/108

(52) U.S. Cl. CPC H01L 21/76229; H01L 27/10814; H01L 27/10894; H01L 27/10897; H01L 27/10823

(57) ABSTRACT

A method of fabricating a semiconductor device includes preparing a substrate including a cell region and a peripheral region having different active region densities, forming cell trenches for limiting cell active regions in the cell region so that the cell active regions are formed to be spaced apart by a first width in a first direction and by a second width in a second direction, forming peripheral trenches for limiting a peripheral active region in the peripheral region, and forming, in the cell trenches, a first insulating layer continuously extending in the first and second directions and contacting sidewalls of the cell active regions, and having a thickness equal to or greater than half of the first width and less than half of the second width.

### CROSS-REFERENCE TO RELATED APPLICATION

This U.S. non-provisional patent application claims priority under 35 U.S.C. § 119 to and the benefit of Korean Patent Application No. 10-2018-0002831, filed on Jan. 9, 2018, in the Korean Intellectual Property Office (KIPO), the disclosure of which is incorporated herein by reference in its entirety.

### BACKGROUND

### 1. Field

The present inventive concepts relate to a semiconductor device including an isolation layer and a method of fabricating the same.

### 2. Discussion of Related Art

With improvement in the integration of semiconductor devices, the linewidth and interval of patterns are reduced, and individual unit elements included in semiconductor devices are gradually getting closer to each other. Accordingly, the function of isolation layers for electrically separating individual unit elements is becoming more important.

In a cell region, isolation layers formed of an oxide cause faulty dents, degradation of dispersion, and the like. For this reason, isolation layers in the cell region may be heterogeneous layers including an oxide and a nitride.

Since isolation layers are formed together in the cell region and a peripheral circuit region, isolation layers including an oxide and a nitride may be included in the peripheral circuit region also. In a sub-word line driving region of the peripheral circuit region, a p-type metal oxide semiconductor (PMOS) transistor may undergo hot electron induced punch-through (HEIP) effects due to the nitride included in the isolation layer.

### SUMMARY

The present inventive concepts are directed to providing a semiconductor device capable of reducing or minimizing hot electron induced punch-through (HEIP) effects in a sub-word line driving region of a peripheral circuit region.

In addition, the present inventive concepts are directed to providing a method of fabricating a semiconductor device capable of reducing or minimizing HEIP effects in a sub-word line driving region of a peripheral circuit region.

A semiconductor device according to an example embodiment of the present inventive concepts includes: a substrate including a cell region and a peripheral region having different active region densities; cell active regions spaced apart in the cell region by a first width in a first direction and by a second width in a second direction; a peripheral active region formed in the peripheral region; a cell isolation layer configured to limit the cell active regions; and a peripheral isolation layer configured to limit the peripheral active region. The cell isolation layer includes a first insulating layer formed to come into contact with sidewalls of the cell active regions and configured to continuously extend in the first and second directions, and a thickness of the first insulating layer is equal to or greater than half of the first width and less than half of the second width.

In an example embodiment, the cell isolation layer may further include a second insulating layer surrounded by the first insulating layer between the cell active regions spaced apart by the second width.

In an example embodiment, the cell isolation layer may further include a third insulating layer surrounded by the second insulating layer between the cell active regions spaced apart by the second width.

In an example embodiment, the semiconductor device may further include a word line formed to extend in an X-axis direction in the cell region, and an upper surface of the third insulating layer may be formed at a lower level than a lower surface of the word line.

In an example embodiment, the peripheral isolation layer may include, on a sidewall of the peripheral active region, an insulating layer having a lesser thickness than the first insulating layer.

In an example embodiment, the peripheral isolation layer may include a gap-fill insulating layer formed on the insulating layer.

In an example embodiment, the insulating layer and the gap-fill insulating layer may be oxides.

A method of fabricating a semiconductor device according to an example embodiment of the present inventive concepts includes: preparing a substrate including a cell region and a peripheral region having different active region densities; forming cell trenches for limiting cell active regions in the cell region so that the cell active regions are formed to be spaced apart by a first width in a first direction and by a second width in a second direction; forming peripheral trenches for limiting a peripheral active region in the peripheral region; and forming, in the cell trenches, a first insulating layer continuously extending in the first and second directions while coming in contact with sidewalls of the cell active regions, and having a thickness equal to or greater than half of the first width and less than half of the second width.

In an example embodiment, the cell trenches may include first cell trenches formed with the first width between the cell active regions spaced apart in the first direction and second cell trenches formed with the second width between the cell active regions spaced apart in the second direction, and the peripheral trenches may include first peripheral trenches formed with a relatively small third width and a second peripheral trench formed with a relatively large fourth width.

In an example embodiment, the first peripheral trenches may have a critical dimension (CD) that is 1 to 3 times a CD of the first cell trenches and 0.5 to 1.5 times a CD of the second cell trenches.

In an example embodiment, the method may further include forming a second insulating layer on the first insulating layer in the second cell trenches and on surfaces of the peripheral trenches to a lesser thickness than the first insulating layer so that a sum of the thicknesses of the first insulating layer and the second layer is less than half of the second width.

In an example embodiment, the method may further include forming a third insulating layer on the second insulating layer in the second cell trenches and the peripheral trenches to completely fill residual spaces surrounded by the second insulating layer in the second cell trenches.

In an example embodiment, a sum of the thickness of the second insulating layer and a thickness of the third insulating layer may be less than half of the third width.

In an example embodiment, the method may further include forming a gap-fill insulating layer on the second insulating layer in the peripheral trenches so that a sum of the thickness of the second insulating layer and a thickness of the gap-fill insulating layer is equal to or greater than half of the third width.

A method of fabricating a semiconductor device according to an example embodiment of the present inventive concepts includes: preparing a substrate including a cell region and a peripheral region having different active region densities; forming cell trenches for limiting cell active regions in the cell region so that the cell active regions are formed to be spaced apart by a first width in a first direction and by a second width in a second direction; forming peripheral trenches for limiting a peripheral active region in the peripheral region; forming, in the cell trenches, a first insulating layer coming in contact with sidewalls of the cell active regions; forming a peripheral isolation layer in the peripheral trenches; and forming a second insulating layer surrounded by the first insulating layer and a third insulating layer surrounded by the second insulating layer at centers between the cell active regions spaced apart by the second width.

In an example embodiment, the first insulating layer may continuously extend in the first and second directions, and a thickness of the first insulating layer may be equal to or greater than half of the first width and less than half of the second width.

In an example embodiment, a sum of the thickness of the first insulating layer and thicknesses of the second insulating layer and the third insulating layer may be equal to or greater than half of the first width.

In an example embodiment, the peripheral isolation layer may include an insulating layer coming in contact with a sidewall of the peripheral active region and having a lesser thickness than the first insulating layer.

In an example embodiment, the method may further include forming an intermediate insulating layer on the insulating layer.

In an example embodiment, a sum of the thickness of the insulating layer and a thickness of the intermediate insulating layer may be less than half of a width of the peripheral trenches.

### BRIEF DESCRIPTION OF THE DRAWINGS

The above and other objects, features and advantages of the present inventive concepts will become more apparent to those of ordinary skill in the art by describing example embodiments thereof in detail with reference to the accompanying drawings, in which:

FIG. 1 is a top-down view showing a partial configuration of a semiconductor device according to an example embodiment of the present inventive concepts;

FIG. 2 is a top-down view showing configurations of portions corresponding to a first region I and a second region II in FIG. 1 according to an example embodiment;

FIG. 3 shows cross-sectional views taken along lines A-A′, B-B′, C-C′, and D-D′ of FIG. 2;

FIG. 4 is a top-down view showing configurations of portions of a semiconductor device corresponding to FIG. 2 according to another example embodiment of the present inventive concepts;

FIG. 5 shows cross-sectional views taken along lines A-A′, B-B′, C-C′, and D-D′ of FIG. 4;

FIG. 6 shows a schematic layout of the first region I of a semiconductor device according to an example embodiment of the present inventive concepts;

FIG. 7 shows cross-sectional views taken along lines A-A′, B-B′, and C-C′ of FIG. 6;

FIG. 8A is a cross-sectional view of the second region II according to an example embodiment of the present inventive concepts;

FIG. 8B is a cross-sectional view of the second region II according to an example embodiment of the present inventive concepts;

FIGS. 9 to 19 are cross-sectional views illustrating, in order of processing, a method of fabricating a semiconductor device according to an example embodiment of the present inventive concepts;

FIG. 20 is a block diagram showing a layout of a semiconductor device according to an example embodiment of the present inventive concepts;

FIG. 21 is a block diagram showing signals of a semiconductor device according to an example embodiment of the present inventive concepts; and

FIG. 22 is a circuit diagram illustrating one sub-word line driving circuit according to an example embodiment of the present inventive concepts.

### DETAILED DESCRIPTION OF EXAMPLE EMBODIMENTS

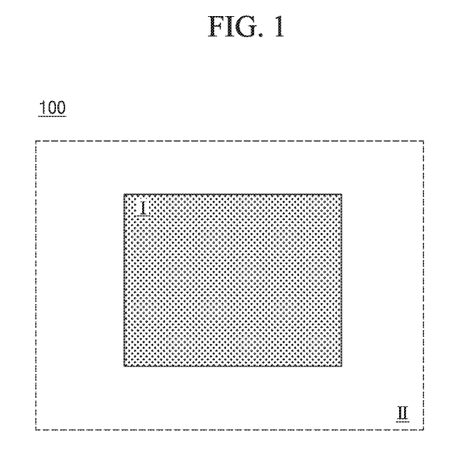

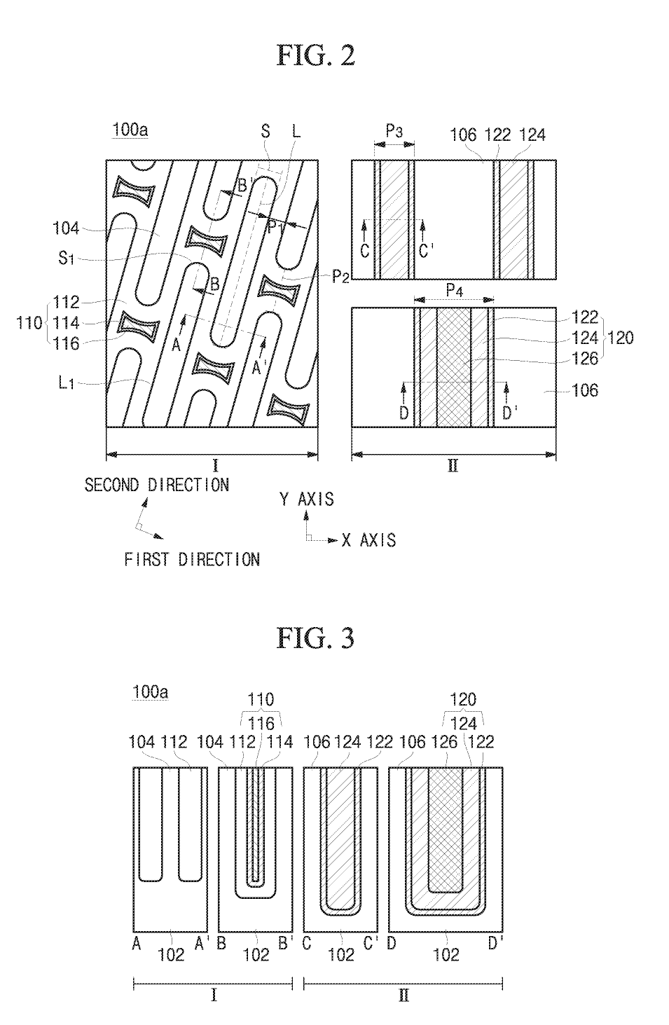

FIG. 1 is a top-down view showing a partial configuration of a semiconductor device according to an example embodiment of the present inventive concepts. FIG. 2 is a top-down view showing configurations of portions corresponding to a first region I and a second region II in FIG. 1 according to an example embodiment. FIG. 3 shows cross-sectional views taken along lines A-A′, B-B′, C-C′, and D-D′ of FIG. 2.

Referring to FIGS. 1 to 3, a semiconductor device 100 according to an example embodiment of the present inventive concepts may include a substrate 102 that has the first region I and the second region II having different active region densities.

The substrate 102 may be formed of a semiconductor substrate such as a silicon wafer. The substrate 102 may include monocrystalline silicon, polycrystalline silicon, or amorphous silicon. The substrate 102 may include at least one selected from among Ge, SiGe, SiC, GaAs, InAs, and InP. The substrate 102 may include a conductive region.

The first region I may be a high-density region whose active region density is relatively high, and the second region II may be a low-density region whose active region density is relatively low.

The first region I may be a cell array region of a semiconductor memory device. As an example, a volatile memory cell array such as a dynamic random access memory (DRAM) may be formed in the first region I. Alternatively, a non-volatile memory cell array such as a flash memory may be formed in the first region I.

In the second region II, peripheral circuits that are electrically connected to cell arrays formed in the first region may be formed. The second region II may include a region in which no cell array is formed, such as a core region. From now on, the term “peripheral circuit region” may denote a region in which the aforementioned peripheral circuits are formed or a core region.

Although FIG. 1 shows that the first region I is surrounded by the second region II, this is merely for illustration, and example embodiments of the present inventive concepts are not limited to the disposition of FIG. 1. The first and second regions I and II may have another configuration.

Referring to FIGS. 2 and 3, the semiconductor device 100 according to an example embodiment of the present inventive concepts may include a cell active region 104 and a cell isolation layer 110 in the first region I of the substrate 102. The cell isolation layer 110 may limit the cell active region 104.

The cell active region 104 may include an upper surface having a short axis S in a first direction and having a long axis L in a second direction. The cell active region 104 may include a short sidewall S1 having the same width as the short axis S and a long sidewall L1 parallel with the long axis L.

A plurality of cell active regions 104 may be formed. The plurality of cell active regions 104 may be spaced apart from each other by a first width P1 in the first direction. Also, the plurality of cell active regions 104 may be spaced apart from each other by a second width P2, which is greater than the first width P1, in the second direction.

The plurality of cell active regions 104 may be repeatedly and regularly formed in the first and second directions. The plurality of cell active regions 104 may be arranged to partially overlap each other in the first direction. The plurality of cell active regions 104 may be arranged in lines in the second direction.

In an example embodiment, the cell isolation layer 110 may include a first insulating layer 112, second insulating layers 114, and third insulating layers 116.

The first insulating layer 112 may be formed to come in contact with sidewalls of the plurality of cell active regions 104 between the plurality of cell active regions 104 spaced apart from each other. In an example embodiment, the first insulating layer 112 may continuously extend in the second direction while coming in contact with the long sidewalls L1 of the cell active regions 104. The first insulating layer 112 may continuously extend in the second direction while coming in contact with the short sidewalls S1 of the cell active regions 104.

A thickness of the first insulating layer 112 may be equal to or greater than half of the first width P1. Therefore, the first insulating layer 112 may completely fill gaps between the plurality of cell active regions 104 that are spaced apart by the first width P1 in the first direction. Also, the first insulating layer 112 may be thinner than half of the second width P2. As an example, the first insulating layer 112 may be formed of an oxide.

The second insulating layers 114 may be formed between the plurality of cell active regions 104 that are spaced apart by the second width P2 in the second direction. The second insulating layers 114 may be formed on the first insulating layer 112. Side surfaces and lower surfaces of the second insulating layers 114 may be surrounded by the first insulating layer 112. The second insulating layers 114 may be formed so that the sum of the thickness of the first insulating layer 112 and a thickness of the second insulating layers 114 is less than half of the second width P2. As an example, the second insulating layers 114 may be formed of an oxide.

The third insulating layers 116 may be formed between the plurality of cell active regions 104 that are spaced apart by the second width P2 in the second direction. The third insulating layers 116 may be formed on the second insulating layers 114. Side surfaces and lower surfaces of the third insulating layers 116 may be surrounded by the second insulating layers 114. As an example, the third insulating layers 116 may be formed of a nitride.

The semiconductor device 100 according to an example embodiment of the present inventive concepts may include a peripheral active region 106 and a peripheral isolation layer 120 in the second region II of the substrate 102. The peripheral isolation layer 120 may limit the peripheral active region 106.

A plurality of peripheral active regions 106 may be formed. The plurality of peripheral active regions 106 may be spaced apart from each other by a third width P3, which is a relatively small width. Also, the plurality of peripheral active regions 106 may be spaced apart from each other by a fourth width P4, which is a relatively large width.

In an example embodiment, the peripheral isolation layer 120 may include an insulating layer liner 122, a gap-fill insulating layer 124, and a trench insulating layer 126.

The insulating layer liner 122 may be formed to come in contact with sidewalls of the plurality of peripheral active regions 106 between the peripheral active regions 106. In other words, the insulating layer liner 122 may be formed between a plurality of peripheral active regions 106 spaced apart from each other by the third width P3. Also, the insulating layer liner 122 may be formed between a plurality of peripheral active regions 106 spaced apart from each other by the fourth width P4. The insulating layer liner 122 may have a lesser thickness than the first insulating layer 112. As an example, the insulating layer liner 122 may be formed of the same material as the second insulating layers 114.

The gap-fill insulating layer 124 may be formed on the insulating layer liner 122 between the plurality of peripheral active regions 106 spaced apart from each other. The gap-fill insulating layer 124 may be formed to come in contact with the insulating layer liner 122. The gap-fill insulating layer 124 may be formed so that the sum of a thickness of the gap-fill insulating layer 124 and the thickness of the insulating layer liner 122 is greater than half of the third width P3. Also, the gap-fill insulating layer 124 may be formed so that the sum of the thickness of the gap-fill insulating layer 124 and the thickness of the insulating layer liner 122 is less than half of the fourth width P4. As an example, the gap-fill insulating layer 124 may be formed of an oxide.

The trench insulating layer 126 may be formed between the plurality of peripheral active regions 106 spaced apart from each other by the fourth width P4. The trench insulating layer 126 may be formed to come in contact with the gap-fill insulating layer 124 on the gap-fill insulating layer 124. The trench insulating layer 126 may be formed to completely fill a gap between the plurality of peripheral active regions 106 spaced apart by the fourth width P4. As an example, the trench insulating layer 126 may be formed of a material different from those of the insulating layer liner 122 and the gap-fill insulating layer 124, but is not limited thereto.

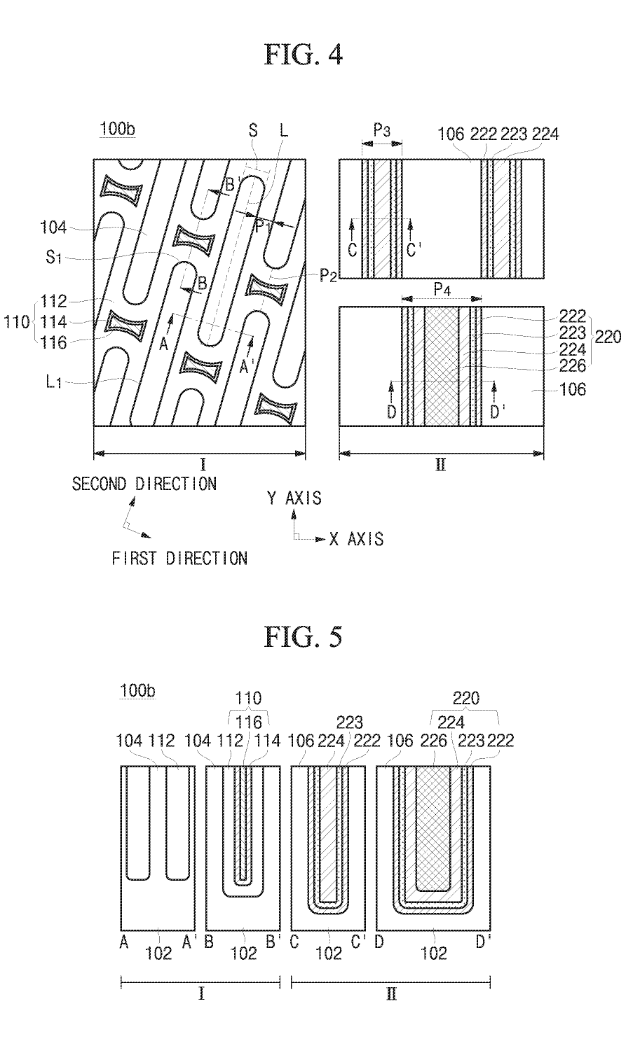

FIG. 4 is a top-down view showing configurations of portions of a semiconductor device corresponding to FIG. 2 according to another example embodiment of the present inventive concepts. FIG. 5 shows cross-sectional views taken along lines A-A′, B-B′, C-C′, and D-D′ of FIG. 4. From now on, reference numerals identical to those of FIGS. 2 and 3 indicate like elements, and duplicate descriptions thereof will be omitted for brevity.

Referring to FIGS. 4 and 5, a peripheral isolation layer 220 according to an example embodiment of the present inventive concepts may further include an intermediate insulating layer 223. The intermediate insulating layer 223 may be formed between an insulating layer liner 222 and a gap-fill insulating layer 224. Side surfaces and a lower surface of the intermediate insulating layer 223 may be surrounded by the insulating layer liner 222. Also, side surfaces and a lower surface of the gap-fill insulating layer 224 may be surrounded by the intermediate insulating layer 223.

The intermediate insulating layer 223 may be formed so that the sum of a thickness of the intermediate insulating layer 223 and a thickness of the insulating layer liner 222 is less than half of the third width P3. As an example, the intermediate insulating layer 223 may be formed of a polysilicon layer.

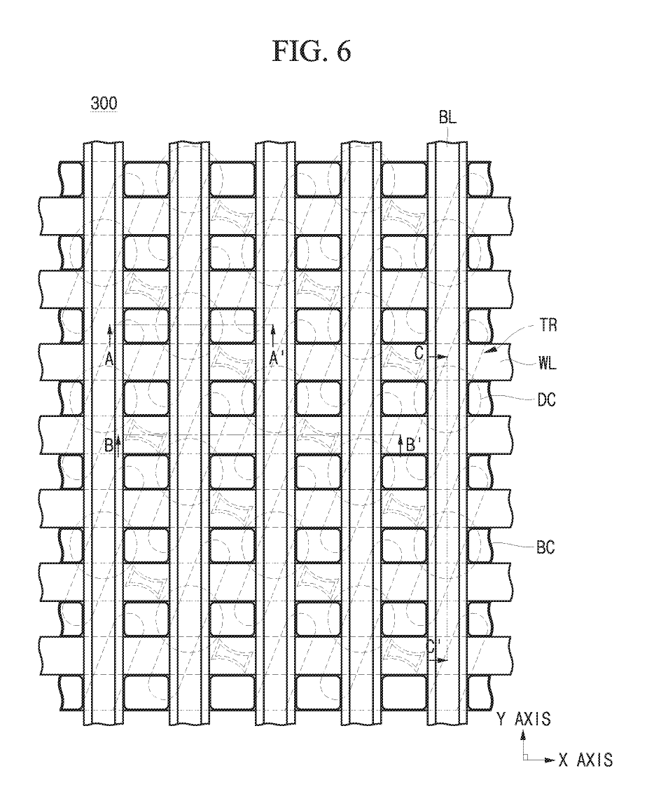

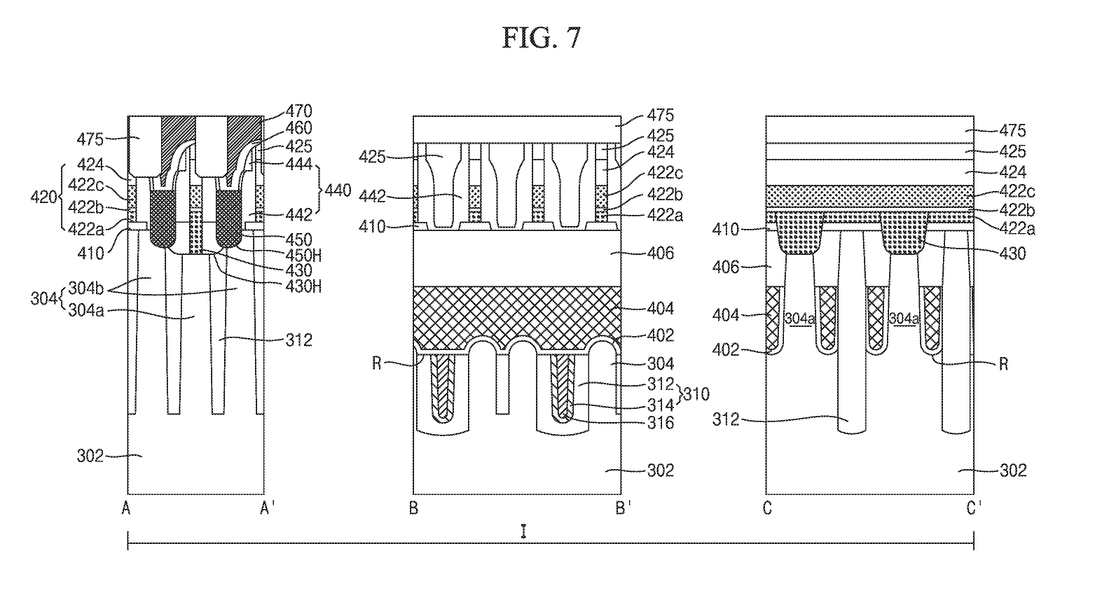

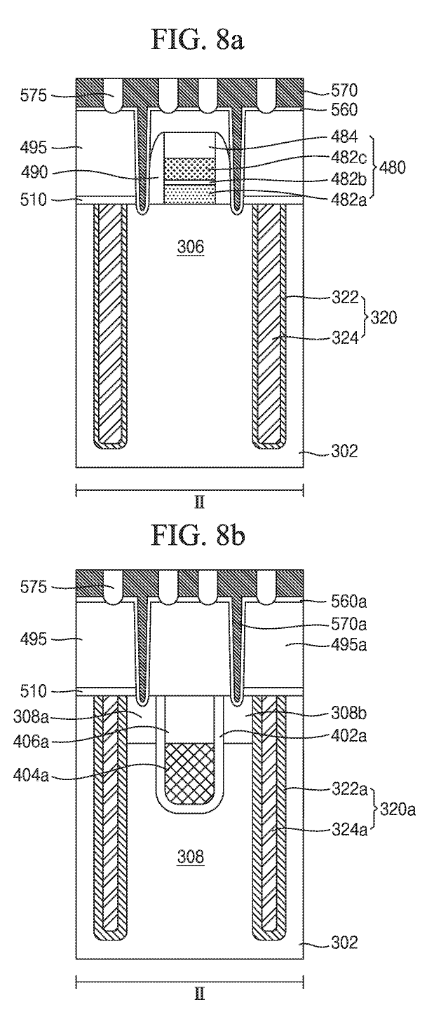

FIG. 6 shows a schematic layout of the first region I of a semiconductor device according to an example embodiment of the present inventive concepts. FIG. 7 shows cross-sectional views taken along lines A-A′, B-B′, and C-C′ of FIG. 6. FIG. 8A is a cross-sectional view of the second region II of the semiconductor device according to an example embodiment of the present inventive concepts. FIG. 8B is a cross-sectional view of the second region II of the semiconductor device according to an example embodiment of the present inventive concepts.

Referring to FIGS. 6 and 7, in the first region I of a semiconductor device 300, cell active regions 304 may be limited by cell isolation layers 310. The cell active regions 304 may be arranged diagonally along an X-axis and arranged in lines along a Y-axis. The cell isolation layers 310 may include first insulating layers 312 and second insulating layers 314 formed of an oxide. Also, the cell isolation layers 310 may include third insulating layers 316 formed of a nitride.

Word lines WL may extend to traverse the cell active regions 304 in an X-axis direction and may be arranged in parallel with each other in a Y-axis direction. On the word lines WL, bit lines BL may extend in the Y-axis direction and may be arranged in parallel with each other in the X-axis direction. The bit lines BL may be connected to the cell active regions 304 through direct contacts DC.

Each of storage node contacts BC may be formed between two bit lines adjacent to each other among the bit lines BL. The storage node contacts BC may be connected to the cell active regions 304 through the direct contacts DC. The storage node contacts BC may be arranged in lines in the X-axis and Y-axis directions.

On a substrate 302 of the semiconductor device 300, recess regions R for forming transistors TR may be formed. The recess regions R may be formed to extend as line patterns having a fixed width. The recess regions R may be formed in parallel in the X-axis direction to traverse the cell active regions 304 and the cell isolation layers 310. The recess regions R may be formed in both edge portions of the cell active regions 304.

The transistors TR may be formed in the cell active regions 304. The transistors TR may include gate insulating layers 402, gate electrodes 404, gate capping layers 406, first impurity regions 304a, and second impurity regions 304b.

The gate insulating layers 402 may be formed on internal surfaces of the recess regions R. The gate insulating layers 402 may be formed between the cell active regions 304 and the gate electrodes 404.

The gate electrodes 404 may be disposed on the gate insulating layers 402. The cell isolation layers 310 and the cell active regions 304 may face the gate electrodes 404 with the plurality of gate insulating layers 403 interposed therebetween. Upper surfaces of the first insulating layers 312 may come in contact with lower surfaces of the gate insulating layers 402. Upper surfaces of the third insulating layers 316 may come in contact with lower surfaces of the gate insulating layers 402.

As an example, the gate insulating layers 402 may be formed of at least one selected from among an insulating material such as a silicon oxide or a silicon oxynitride, and a metal oxide such as a hafnium oxide, an aluminum oxide, or a zirconium oxide. The gate insulating layers 402 may be formed through an atomic layer deposition (ALD) process.

The gate electrodes 404 may be buried under the recess regions R. Upper surfaces of the gate electrodes 404 may be positioned at a lower level than upper surfaces of the cell active regions 304. As an example, the gate electrodes 404 may be formed of at least one of a silicon oxide layer, a silicon oxynitride layer, and a combination thereof. The gate electrodes 404 may constitute the word lines WL.

A level of portions of the recess regions R that face the cell active regions 304 may be higher than a level of portions of the recess regions R that face the cell isolation layers 310. The lower surfaces of the gate electrodes 404 are concave and convex to correspond to a lower surface profile of the recess regions R, and saddle fin field effect transistors (FINFETs) may be formed in the cell active regions 304.

The gate capping layers 406 may be formed to cover the gate electrodes 404 from above. The gate capping layers 406 may fill upper portions of the recess regions R. Upper surfaces of the gate capping layers 406 may be positioned at the same level as the upper surfaces of the cell active regions 304. The gate capping layers 406 may include an insulating material. As an example, the gate capping layers 406 may be nitride layers.

Each of the first impurity regions 304a may be disposed in cell active regions 304 positioned between one pair of gate electrodes 404. Second impurity regions 304b may be formed in cell active regions 304 positioned on both sides of one pair of gate electrodes 404. The first impurity regions 304a and the second impurity regions 304b may be doped with an n-type impurity. The first impurity regions 304a and the second impurity regions 304b may serve as source and/or drain regions.

Buffer insulating layer patterns 410 may be formed on the cell active regions 304 and the cell isolation layers 310. As an example, the buffer insulating layer patterns 410 may be formed of a silicon oxide, a silicon nitride, or a combination thereof. The buffer insulating layer patterns 410 may be formed as a single layer or a plurality of layers.

Bit-line structures 420 may include bit lines 422a, 422b, and 422c and hard mask patterns 424. The bit lines 422a, 422b, and 422c may extend to traverse the word lines WL in the Y-axis direction and may be arranged in parallel with each other in the X-axis direction. The bit lines 422a, 422b, and 422c may be connected to the cell active regions 304 through first contact plugs 430.

The bit lines 422a, 422b, and 422c may include first conductive patterns 422a, second conductive patterns 422b, and metal-containing layers 422c. As the bit lines 422a, 422b, and 422c, the second conductive patterns 422b may be formed on the first conductive patterns 422a, and the metal-containing layers 422c may be formed on the second conductive patterns 422b. The bit lines 422a, 422b, and 422c may be formed as triple-layered structures including the first conductive patterns 422a, the second conductive patterns 422b, and the metal-containing layers 422c, but are not limited thereto. As an example, the bit lines 422a, 422b, and 422c may be formed as single, double, or quadruple structures or beyond.

As an example, the first conductive patterns 422a and the second conductive patterns 422b may be formed of polysilicon layers doped with impurities. The metal-containing layers 422c may include a metal such as tungsten, titanium, tantalum, etc., or a conductive metal nitride such as nitrides thereof. The first conductive patterns 422a, the second conductive patterns 422b, and the metal-containing layers 422c are not limited to the materials.

The hard mask patterns 424 may be formed on the bit lines 422a, 422b, and 422c. The hard mask patterns 424 may include the aforementioned insulating materials. As an example, the hard mask patterns 424 may be a nitride.

Insulating patterns 425 may be formed on the bit-line structures 420. The insulating patterns 425 may also be formed between the bit-line structures 420.

First contact plugs 430 may be buried in first contact holes 430H that expose parts of the cell active regions 304, and may be electrically connected to the cell active regions 304. The first contact holes 430H may pass through the first impurity regions 304a of the cell active regions 304, the cell isolation layers 310 adjacent to the first impurity regions 304a, and parts of the gate capping layers 406, such that lower ends of the first contact holes 430H may be positioned lower than the upper surfaces of the cell active regions 304. The first contact plugs 430 may constitute the direct contacts DC that connect the bit lines 422a, 422b, and 422c to the cell active regions 304.

Lower ends of the first contact plugs 430 may be insulated from the gate electrodes 404 by the gate capping layers 406. As an example, the first contact plugs 430 may be formed of epitaxial silicon layers. The first contact plugs 430 may include polysilicon doped with an impurity.

Insulating spacers 440 may be disposed between internal surfaces of the first contact holes 430H and the first contact plugs 430. As the insulating spacers 440, an insulating material may be buried in the contact holes 430H to surround side surfaces of the first contact plugs 430. The insulating spacers 440 may insulate the first contact plugs 430 from second contact plugs 450 adjacent to the first contact plugs 430. As an example, the insulating spacers 440 may be formed as multi-layered structures which are sequentially stacked on both sides of the bit-line structures 420.

Second contact plugs 450 may be formed to be buried in second contact holes 450H formed between two bit lines 422a, 422b, and 422c adjacent to each other. The second contact plugs 450 may extend to upper portions of two bit lines 422a, 422b, and 422c adjacent to each other. In an example embodiment, the second contact plugs 450 may be arranged in lines in the X-axis and Y-axis directions. The second contact plugs 450 may constitute the storage node contacts BC.

Barrier layers 460 may be formed on the insulating spacers 440 and the second contact plugs 450. The barrier layers 460 may be omitted.

In an example embodiment, landing pads 470 may be formed to cover the second contact plugs 450 and the insulating spacers 440. The landing pads 470 and the second contact plugs 450 may connect lower electrodes (not shown) of capacitors formed on the bit lines 422a, 422b, and 422c to the cell active regions 304. The landing pads 470 may be disposed to partially overlap the second contact plugs 450.

Referring to FIG. 8A, in the second region II of the semiconductor device 300, a peripheral active region 306 may be formed by peripheral isolation layers 320 formed of an oxide.

The peripheral isolation layers 320 may include insulating layer liners 322 and gap-fill insulating layers 324. The insulating layer liners 322 may have a lesser thickness than the first insulating layers 312 of FIG. 7. The insulating layer liners 322 may be formed simultaneously with the second insulating layers 314 of FIG. 7.

The insulating layer liners 322 and the gap-fill insulating layers 324 may all be formed of oxides. In other words, the peripheral isolation layers 320 may be formed of oxides. The peripheral isolation layers 320 formed of oxides may reduce or prevent hot electron induced punch-through (HEIP) effects in a sub-word line driving region. The peripheral isolation layers 320 formed of oxides may reduce or prevent the occurrence of problems such as an increase in power consumption, a reduction in operating speed, a reduction in punch-through voltage, etc., and/or may improve a cell refresh operation.

A gate electrode structure 480 may be formed on the peripheral active region 306. The gate electrode structure 480 may include a gate first conductive pattern 482a, a gate second conductive pattern 482b, and a gate metal-containing layer 482c.

The gate first conductive pattern 482a may be formed of a conductive material which is identical to or different from that of the first conductive patterns 422a of the bit lines 422a, 422b, and 422c. As an example, the gate first conductive pattern 482a and the first conductive patterns 422a both may be formed of polysilicon. Meanwhile, even when both are formed of polysilicon, a resistance of the first conductive patterns 422a may become lower than that of the gate first conductive pattern 482a by adjusting process conditions.

The gate second conductive pattern 482b and the gate metal-containing layer 482 may be formed simultaneously with the second conductive patterns 422b and the metal-containing layers 422c, respectively. Therefore, the gate second conductive pattern 482b may be formed of the same conductive material as the second conductive patterns 422b, and the gate metal-containing layer 482c may be formed of the same conductive material as the metal-containing layers 422c.

The gate electrode structure 480 and the bit lines 422a, 422b, and 422c may be formed at different points in time. As an example, the gate first conductive pattern 482a and the first conductive patterns 422a may be formed at different points in time. As an example, the first conductive patterns 422a may be formed first, and then the gate first conductive pattern 482a may be formed.

A gate insulating capping line 484 may be formed on the gate electrode structure 480. The gate insulating capping line 484 may be formed simultaneously with the hard mask patterns 424 of upper bit line portions, and thus may be formed of the same material as the hard mask patterns 424.

Gate insulating spacers 490 may be formed on both sides of the gate electrode structure 480 and the gate insulating capping line 484. The gate insulating spacers 490 may be formed simultaneously with or separately from the insulating spacers 440 of the first region I. When the gate insulating spacers 490 and the insulating spacers 440 are simultaneously formed, the gate insulating spacer 490 may be formed of the same material as the insulating spacers 440.

A gate insulating layer 495 surrounding the gate insulating spacers 490 may be formed on side surfaces and upper surfaces of the gate insulating spacers 490. The gate insulating layer 495 may also be formed on the gate insulating capping line 484. As an example, the gate insulating layer 495 may be formed of a silicon oxide layer, a silicon nitride layer, or a combination thereof.

Contact holes may be formed in the gate insulating layer 495, and a barrier layer 560 may be formed on internal walls of the contact holes. The contact holes and the barrier layer 560 may be respectively formed simultaneously with the second contact holes 450H and the barrier layers 460 of the first region I, and may be formed of the same material.

Conductive lines 570 may be formed on the barrier layer 560. The conductive lines 570 may be formed of the same material as the landing pads 470 of the first region I at the same time as the landing pads 470. The conductive lines 570 may be formed of a metal, a metal nitride, a conductive polysilicon, or a combination thereof. As an example, the conductive lines 570 may include tungsten.

Although not shown in the drawing, a dummy conductive layer may exist in at least a part of the second region II. As an example, during a fabrication process of the semiconductor device 300, patterning is performed to form the gate electrode structure 480 in the second region II, that is, the peripheral circuit region, and in the patterning process, parts of dummy conductive layers may not be removed and may remain.

Referring to FIG. 8B, a buried gate may be formed in the second region II of the semiconductor device 300. The buried gate may be formed to traverse a peripheral active region 308. The buried gate may include a gate insulating layer 402a formed to come in contact with the peripheral active region 308, a gate electrode 404a formed on the gate insulating layer 402a, and a gate capping layer 406a formed on the gate electrode 404a.

Peripheral isolation layers 320a may be formed on both sides of the buried gate. Source and drain patterns 308a and 308b may be formed on both sides of the buried gate. On the peripheral active region 308, an interlayer insulating layer 495a may be formed. Contact holes may be formed in the interlayer insulating layer 495a, and conductive lines may be formed in the contact holes and connected to the source and drain patterns 308a and 308b.

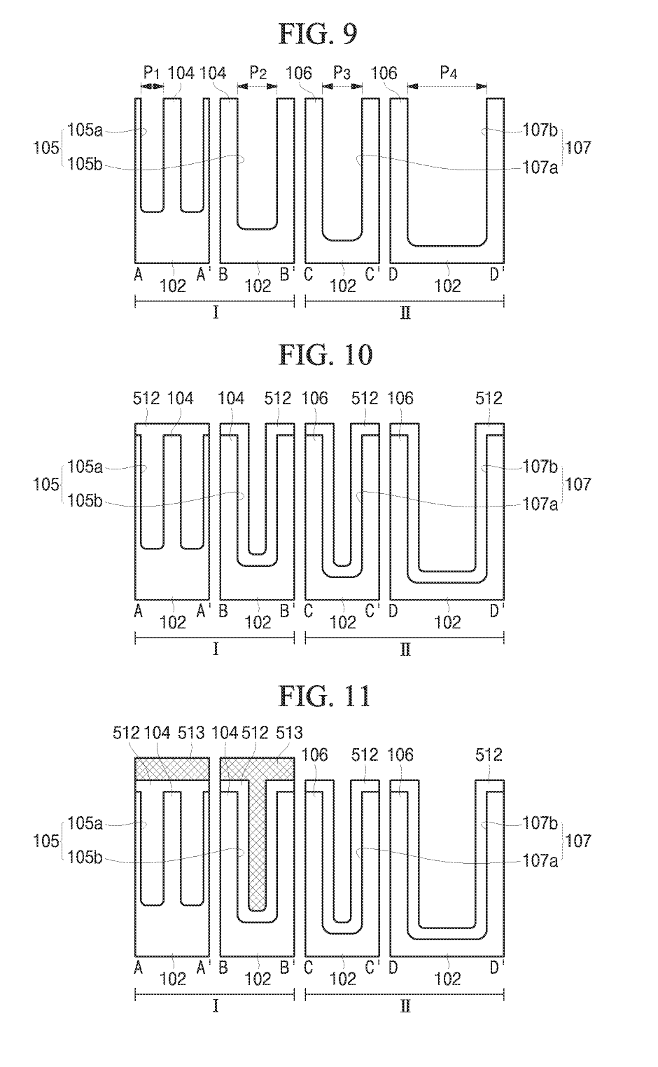

FIGS. 9 to 19 are diagrams illustrating a method of fabricating a semiconductor device according to an example embodiment of the present inventive concepts. Lines A-A′, B-B′, C-C′, and D-D′ of FIGS. 9 to 19 may correspond to lines A-A′, B-B′, C-C′, and D-D′ of FIG. 2 or 4.

Referring to FIG. 9, cell trenches 105 for limiting the cell active regions 104 may be formed in the first region I of the substrate 102, and peripheral trenches 107 for limiting the peripheral active regions 106 may be formed in the second region II. A depth of the cell trenches 105 may be formed to a depth less than that of the peripheral trenches 107 of the second region II due to a loading effect and/or reactive ion etching (RIE) lag.

The cell trenches 105 may include first cell trenches 105a having the relatively small width P1 and second cell trenches 105b having the relatively large width P2. As an example, the first cell trenches 105a and the second cell trenches 105b of the cell trenches 105 may have different depths. As an example, the second cell trenches 105b may be formed to a depth greater than that of the first cell trenches 105a due to RIE lag.

The peripheral trenches 107 may include a first peripheral trench 107a having a relatively small width P3 and a second peripheral trench 107b having a relatively large width P4. In an exemplary embodiment, an upper end of the first peripheral trench 107a may have a critical dimension (CD) that is 1 to 3 times a CD of upper ends of the first cell trenches 105a. Also, the upper end of the first peripheral trench 107a may have a CD that is 0.5 to 1.5 times a CD of an upper end of the second cell trenches 105b.

Such CDs of peripheral trenches may result from a reduction in feature size of the semiconductor device. Accordingly, in a sub-word line driving region of the peripheral circuit region, a peripheral isolation layer may be formed of an oxide to maintain electrical characteristics of adjacent individual elements of the semiconductor device. Meanwhile, a process of obtaining a residual space for removing a nitride from the first peripheral trench 107a may be required so that the peripheral isolation layer is formed of an oxide.

Referring to FIG. 10, a first insulating layer 512 may be formed on surfaces of the cell trenches 105 and the peripheral trenches 107 in the first region I and the second region II.

A thickness of the first insulating layer 512 may be equal to or greater than half of the width P1 of the first cell trenches 105a, and may be less than half of the width P2 of the second cell trenches 105b. Accordingly, the first insulating layer 512 may be formed so that the first cell trenches 105a having the relatively small width P1 among the cell trenches 105 is completely filled and a residual space remains in the second cell trenches 105b having the relatively large width P2. Also, the first insulating layer 512 may be formed so as not to completely fill the peripheral trenches 107 of the second region II.

As an example, seams may exist in the first insulating layer 512 in the cell trenches 105 as the result of a deposition process. Voids caused by the seams may exist in the first insulating layer 512 in the cell trenches 105.

The first insulating layer 512 may conformally cover internal walls of the second cell trenches 105b and the peripheral trenches 107. As an example, the first insulating layer 512 may improve cell transistor switching characteristics by reducing consumption caused by oxidation of the cell active regions 104 and obtaining an area necessary for the cell active regions 104 during a follow-up oxidation process.

As an example, the first insulating layer 512 may be formed of a silicon oxide layer. The first insulating layer 512 may be formed by using an ALD process, a chemical vapor deposition (CVD) process, a radical oxidation process, a natural oxidation process, or the like.

Referring to FIG. 11, a photoresist layer 513 may be formed on the first insulating layer 512 in the first region I. The photoresist layer 513 may cover the first region I of the substrate 102 overall. The photoresist layer 513 may not be formed in the second region II of the substrate 102. The photoresist layer 513 may be formed at a selection ratio different from that of the first insulating layer 512.

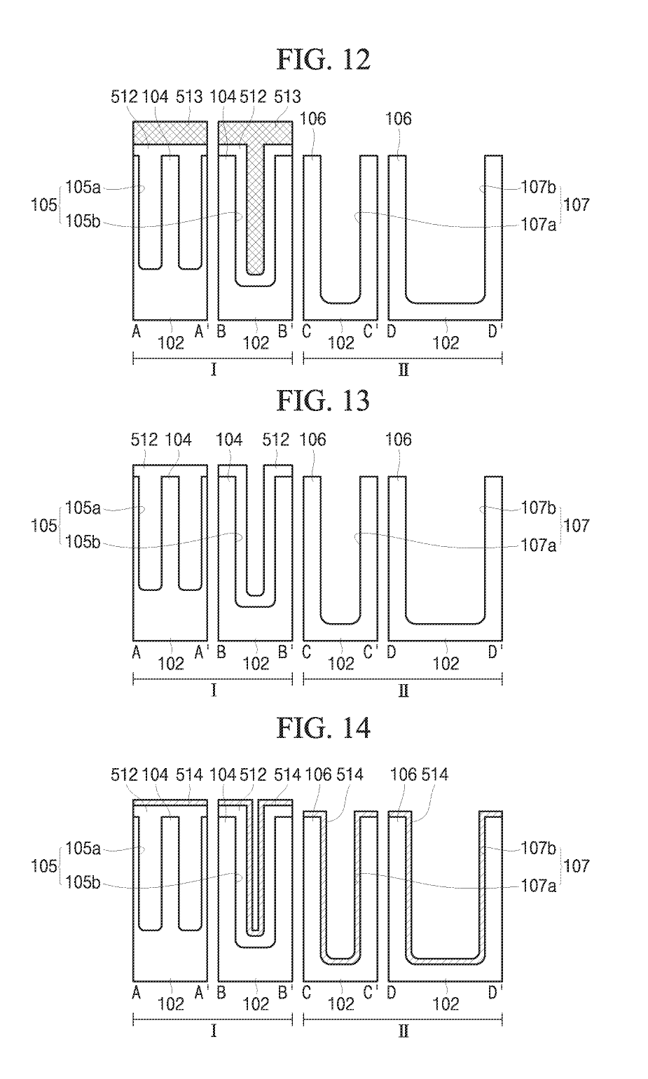

Referring to FIG. 12, the first insulating layer 512 of the second region II may be removed through an etching process using the photoresist layer 513. In the second region II, the first insulating layer 512 may be removed so that an upper surface of the substrate 102 may be exposed.

Referring to FIG. 13, the photoresist layer 513 may be removed from the first region I. As an example, the photoresist layer 513 may be removed through a strip process and/or an ashing process. The photoresist layer 513 may be removed by using the first insulating layer 512 as an etch stop layer.

Referring to FIG. 14, a second insulating layer 514 may be formed in the first region I and the second region II. The second insulating layer 514 may be formed on the first insulating layer 512 in the cell trenches 105. The second insulating layer 514 may be formed on the exposed upper surfaces of the peripheral trenches 107.

The second insulating layer 514 may be formed to a thickness less than that of the first insulating layer 512. Also, a sum of the thicknesses of the second insulating layer 514 and the first insulating layer 512 may be less than half of the second trench width P2. Accordingly, the second cell trench 105b may not be completely filled. In the first peripheral trench 107a, it is possible to obtain a residual space larger than that of a case in which the first insulating layer 512 is formed as shown in FIG. 10. Even when a third insulating layer 516 is formed later, the first peripheral trench 107a may not be completely filled due to the obtained large residual space.

As an example, the second insulating layer 514 may be formed of a silicon oxide layer. The second insulating layer 514 may be formed through an ALD process. Alternatively, the second insulating layer 514 may be formed through a CVD process, a radical oxidation process, a natural oxidation process, or the like.

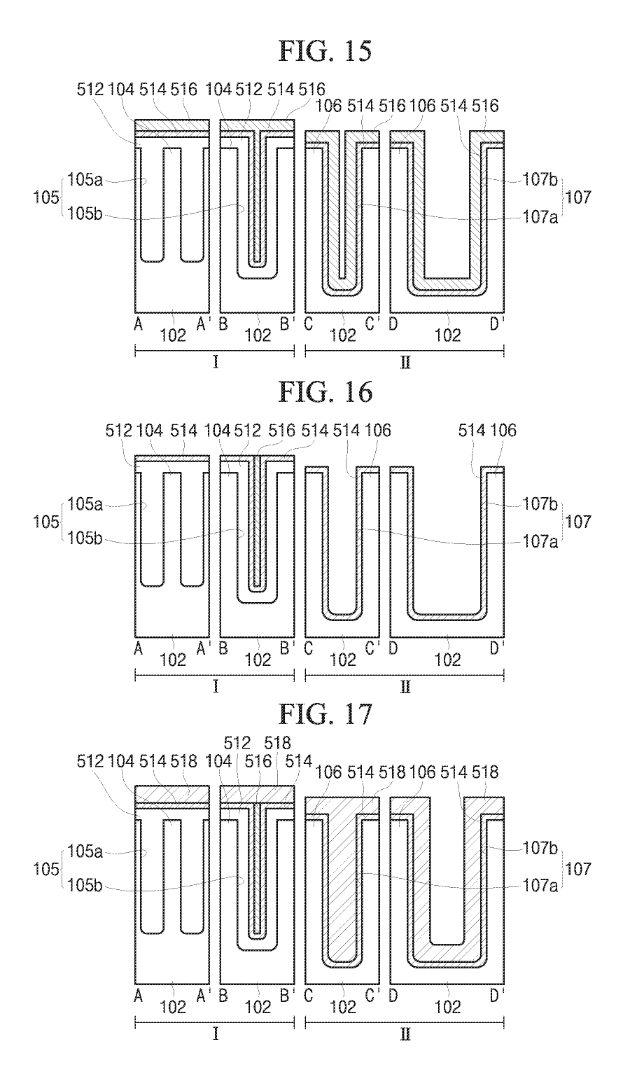

Referring to FIG. 15, the third insulating layer 516 may be formed in the first region I and the second region II. The third insulating layer 516 may be formed on the second insulating layer 514 in the first region I and the second region II. In the second cell trenches 105b, sidewalls and lower surfaces of the third insulating layer 516 may be surrounded by the second insulating layer 514. The third insulating layer 516 may be formed to completely fill the second cell trenches 105b in the first region I. In other words, the third insulating layer 516 may completely fill residual spaces surrounded by the second insulating layer 514 in the second cell trenches 105b.

A sum of a thickness of the third insulating layer 516 and the thickness of the second insulating layer 514 may be less than half of the first peripheral trench width P3. In other words, the third insulating layer 516 does not completely fill the first peripheral trench 107a in the second region II, and may be conformally formed. Accordingly, some residual space may be obtained in the first peripheral trench 107a even after the third insulating layer 516 is formed. The small residual space, which is obtained in the first peripheral trench 107a after the third insulating layer 516 is formed, may allow a strip process of removing the third insulating layer 516 from the first peripheral trench 107a later.

As an example, the third insulating layer 516 may be formed of a silicon nitride layer. The third insulating layer 516 may be formed through an ALD process or a CVD process. Seams may exist in the third insulating layer 516 in the second cell trenches 105b. Voids caused by the seams may exist in the third insulating layer 516 in the second cell trenches 105b.

Referring to FIG. 16, the third insulating layer 516 may be removed from the peripheral trenches 107. As an example, the third insulating layer 516 may be removed through a strip process and/or an ashing process.

An upper surface of the second insulating layer 514 may be exposed in the peripheral trenches 107 from which the third insulating layer 516 has been removed. Also, the peripheral trenches 107 may have residual spaces larger than those of FIG. 15. The third insulating layer 516 is partially removed in the first region I also, but may remain and completely fill the second cell trenches 105b.

Referring to FIG. 17, a gap-fill insulating layer 518 may be formed on the second insulating layer 514 whose upper surface has been exposed. The gap-fill insulating layer 518 may be formed to a thickness so that a sum of the thickness of the second insulating layer 514 and the thickness of the gap-fill insulating layer 518 becomes equal to or greater than half of the first peripheral trench width P3. In other words, the gap-fill insulating layer 518 may be formed to a thickness that is sufficient for completely filling a residual space of the first peripheral trench 107a. Also, the gap-fill insulating layer 518 may be formed not to completely fill the second peripheral trench 107b. In other words, the gap-fill insulating layer 518 may be formed so that a sum of the thickness of the gap-fill insulating layer 518 and the thickness of the second insulating layer 514 is less than half of the width P4 of the second peripheral trench 107b. However, the thickness of the gap-fill insulating layer 518 is not limited thereto, and the gap-fill insulating layer 518 may be formed to completely fill the second peripheral trench 107b.

As an example, the gap-fill insulating layer 518 may be formed of an oxide layer. The gap-fill insulating layer 518 may be formed of at least one selected from among tonen silazen (TOSN), high density plasma (HDP) oxide, flowable oxide (FOX), spin on glass (SOG), undoped silica glass (USG), tetraethyl ortho silicate (TEOS), and low temperature oxide (LTO).

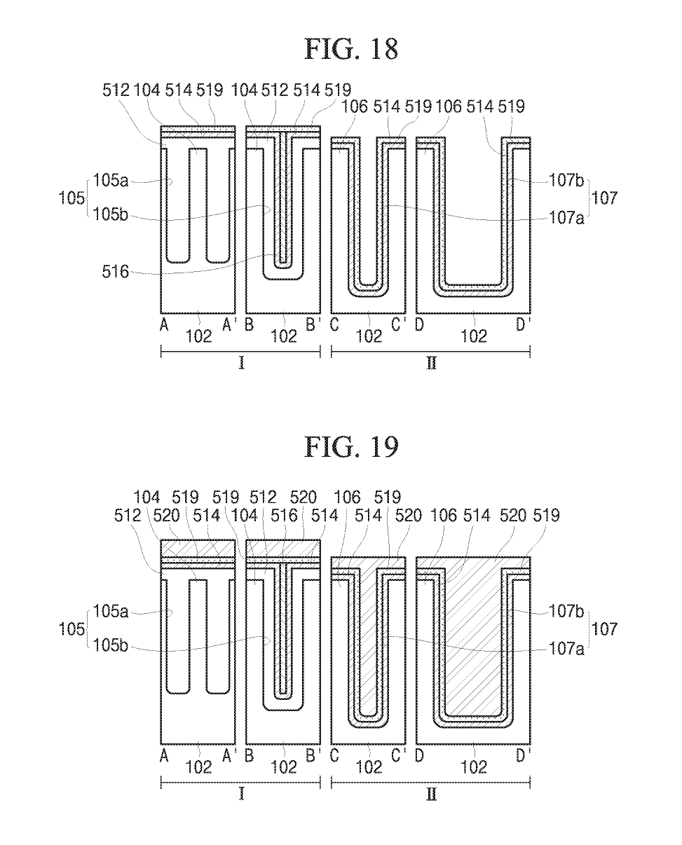

Referring to FIG. 18, before the gap-fill insulating layer 518 is formed, an intermediate insulating layer 519 may be formed on the second insulating layer 514 in the second region II from which the third insulating layer 516 has been removed. A sum of a thickness of the intermediate insulating layer 519 and the thickness of the second insulating layer 514 may be less than half of the width P3 of the first peripheral trench 107a. In other words, the intermediate insulating layer 519 may be conformally formed so as not to completely fill the first peripheral trench 107a. Accordingly, some residual space may be obtained in the first peripheral trench 107a. The intermediate insulating layer 519 may reduce a CD of the first peripheral trench 107a.

As an example, the intermediate insulating layer 519 may be formed of a polysilicon layer. The intermediate insulating layer 519 may be formed by using an ALD process, a CVD process, a radical oxidation process, a natural oxidation process, or the like.

At least a part of the intermediate insulating layer 519 may oxidize while the residual space is being filled, and the oxidation result may constitute a part of the second insulating layer 514. Alternatively, the entire intermediate insulating layer 519 may oxidize, and the oxidation result may constitute the second insulating layer 514. Accordingly, in the second region II, the intermediate insulating layer 519 may not remain between the second insulating layer 514 and a gap-fill insulating layer 520 to be formed later.

Referring to FIG. 19, after the intermediate insulating layer 519 is formed, the gap-fill insulating layer 520 may be formed on the intermediate insulating layer 519. As described above, the gap-fill insulating layer 520 may be formed to a thickness sufficient for completely filling the residual space of the first peripheral trench 107a. Also, the gap-fill insulating layer 520 may be formed to a thickness sufficient for completely filling a residual space of the second peripheral trench 107b, but is not limited thereto.

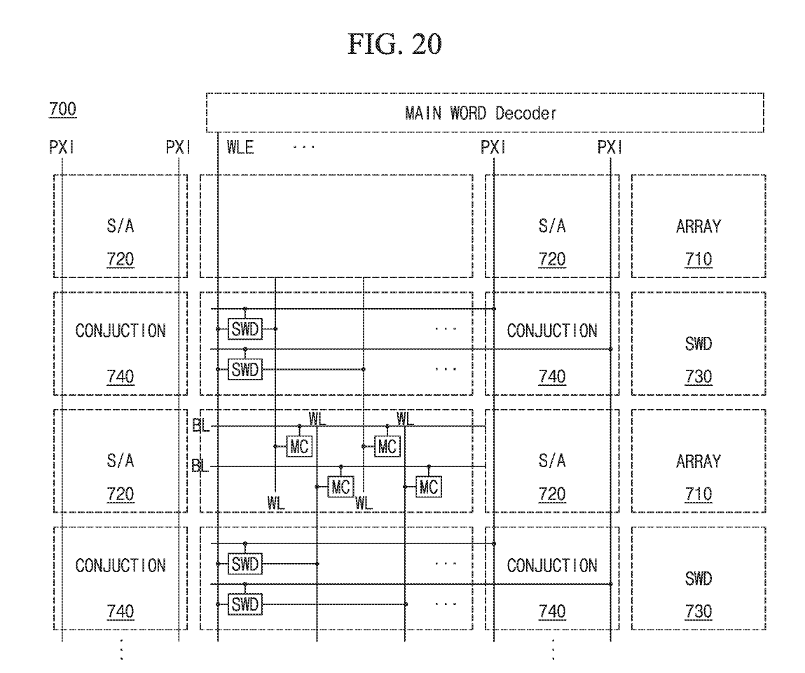

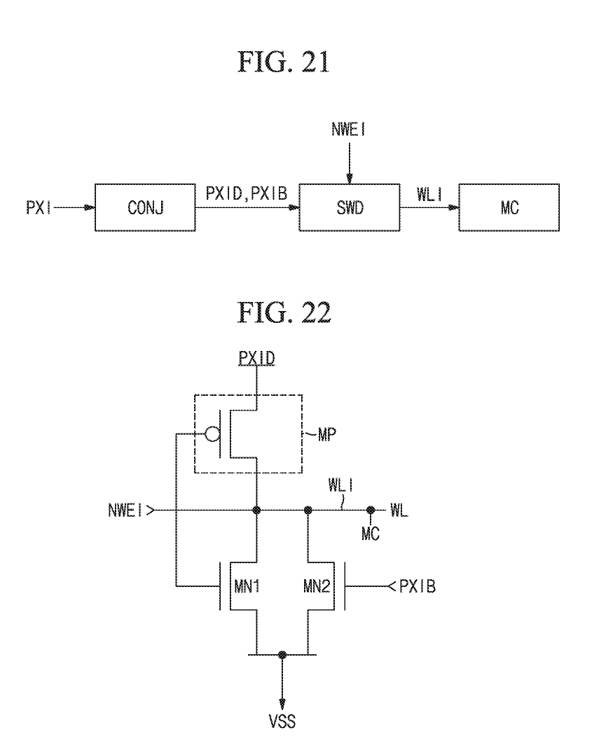

FIG. 20 is a block diagram showing a layout of a semiconductor device according to an example embodiment of the present inventive concepts. FIG. 21 is a block diagram showing signals of a semiconductor device according to an example embodiment of the present inventive concepts. FIG. 22 is a circuit diagram illustrating one sub-word line driving circuit according to an example embodiment of the present inventive concepts.

Referring to FIG. 20, a semiconductor device 700 includes a plurality of sub-arrays 710 which are arranged in a matrix form of rows and columns. Each of the sub-arrays 710 may include a plurality of word lines WL, a plurality of bit lines BL, and a plurality of memory cells MCs arranged at intersections of the word lines WL and the bit lines BL.

Sense amplification regions 720 may be disposed between the sub-arrays 710 arranged in a direction of the bit lines BL. A plurality of sense amplifiers (S/As) are provided in each of the sense amplification regions 720, and each of the S/As may be connected to a bit line BL arranged along a column of adjacent sub-arrays.

S/As in each sense amplification region 720 may be shared by adjacent sub-arrays 710. On both sides of the sub-arrays 710, sub-word line driving regions 730 may be arranged in a direction of the word lines WL.

A plurality of sub-word line drivers SWD may be provided in each sub-word line driving region 730. Some word lines WL of the sub-arrays 710 may be selected/driven by sub-word line drivers SWD disposed on one side (e.g., an upper side of the sub-arrays 710), and other word lines WL may be selected/driven by sub-word line drivers SWD disposed on the other side (e.g., a lower side of the sub-arrays 710). In response to a PXI signal from a main word line WLE connected to a main word decoder and a PXI generator (not shown), each sub-word line driver SWD may select a corresponding sub-word line. Conjunction regions 740 may be disposed between sub-word line driving regions 730 adjacent in a direction of the bit lines BL.

Referring to FIGS. 20 and 21, a first sub-word line control signal PXID and a second sub-word line control signal PXIB may be generated from the conjunction regions 740 based on the PXI signal. Sub-word line driving circuits of the sub-word line drivers SWD may generate word-line driving signals WLI based on a main word-line driving signal NEWI generated from the main word decoder, the first sub-word line control signal PXID, and the second sub-word line control signal PXIB. The sub-arrays 710 may operate in response to the word-line driving signal WLI.

Referring to FIG. 22, each sub-word line driving circuit may include a p-type metal oxide semiconductor (PMOS) transistor MP, a first n-type metal oxide semiconductor (NMOS) transistor MN1, and a second NMOS transistor MN2. The PMOS transistor MP may have a gate to which the main word-line driving signal NEWI is applied, a source to which the first sub-word line control signal PXID is applied, and a drain connected to a node ND. The first NMOS transistor MN1 may have a gate to which the main word-line driving signal NEWI is applied, a drain connected to the node ND, and a source connected to a ground VSS. The second NMOS transistor MN2 may have a gate to which the second sub-word line control signal PXIB is applied, a drain connected to the node ND, and a source connected to the ground VSS. The node ND may be electrically connected to a word line WL.

Example embodiments of the present inventive concepts provide an isolation layer formed of a single oxide layer in a peripheral circuit region.

Example embodiments of the present inventive concepts provide heterogeneous isolation layers including an oxide layer and a nitride layer in a cell region and provide isolation layers that do not include a nitride layer in the peripheral circuit region.

Example embodiments of the present inventive concepts implement a semiconductor device capable of reducing or preventing HEIP effects in a sub-word line driving region of the peripheral circuit region.

Although the example embodiments of the present inventive concepts have been described with reference to the accompanying drawings, these are only exemplary, and those of ordinary skill in the art would appreciate that various modifications and equivalents may be made from the example embodiments. Therefore, the true technical scope of the example embodiments according to the present inventive concepts will be determined by the technical spirit of the following claims.

What is claimed is:

1. A semiconductor device comprising:
a substrate including a cell region and a peripheral region having different active region densities;
cell active regions in the cell region to be spaced apart by a first width in a first direction and by a second width in a second direction;
a peripheral active region in the peripheral region;
a cell isolation layer configured to limit the cell active regions; and
a peripheral isolation layer configured to limit the peripheral active region,
wherein the cell isolation layer includes a first insulating layer in contact with sidewalls of the cell active regions and configured to continuously extend in the first and second directions, and
a thickness of the first insulating layer is equal to or greater than half of the first width and less than half of the second width.

2. The semiconductor device of claim 1, wherein the cell isolation layer further includes a second insulating layer surrounded by the first insulating layer between the cell active regions spaced apart by the second width.

3. The semiconductor device of claim 2, wherein the cell isolation layer further includes a third insulating layer surrounded by the second insulating layer between the cell active regions spaced apart by the second width.

4. The semiconductor device of claim 3, further comprising a word line configured to extend in an X-axis direction in the cell region,
wherein an upper surface of the third insulating layer is at a lower level than a lower surface of the word line.

5. The semiconductor device of claim 1, wherein the peripheral isolation layer includes, on a sidewall of the peripheral active region, an insulating layer having a lesser thickness than the first insulating layer.

6. The semiconductor device of claim 5, wherein the peripheral isolation layer includes a gap-fill insulating layer on the insulating layer.

7. The semiconductor device of claim 6, wherein the insulating layer and the gap-fill insulating layer are oxides.

8. A method of fabricating a semiconductor device, the method comprising:
preparing a substrate including a cell region and a peripheral region having different active region densities;
forming cell trenches for limiting cell active regions in the cell region so that the cell active regions are formed to be spaced apart by a first width in a first direction and by a second width in a second direction;
forming peripheral trenches for limiting a peripheral active region in the peripheral region; and
forming, in the cell trenches, a first insulating layer continuously extending in the first and second directions and contacting sidewalls of the cell active regions, and having a thickness equal to or greater than half of the first width and less than half of the second width.

9. The method of claim 8, wherein the cell trenches include first cell trenches formed with the first width between the cell active regions spaced apart in the first direction and second cell trenches formed with the second width between the cell active regions spaced apart in the second direction, and
the peripheral trenches may include first peripheral trenches formed with a relatively small third width and a second peripheral trench formed with a relatively large fourth width.

10. The method of claim 9, wherein the first peripheral trenches have a critical dimension (CD) that is 1 to 3 times a CD of the first cell trenches and 0.5 to 1.5 times a CD of the second cell trenches.

11. The method of claim 9, further comprising forming a second insulating layer on the first insulating layer in the second cell trenches and on surfaces of the peripheral trenches to a lesser thickness than the first insulating layer so that a sum of the thicknesses of the first insulating layer and the second layer is less than half of the second width.

12. The method of claim 11, further comprising forming a third insulating layer on the second insulating layer in the second cell trenches and the peripheral trenches to completely fill residual spaces surrounded by the second insulating layer in the second cell trenches.

13. The method of claim 12, wherein a sum of the thickness of the second insulating layer and a thickness of the third insulating layer is less than half of the third width.

14. The method of claim 11, further comprising forming a gap-fill insulating layer on the second insulating layer in the peripheral trenches so that a sum of the thickness of the second insulating layer and a thickness of the gap-fill insulating layer is equal to or greater than half of the third width.

15. A method of fabricating a semiconductor device, the method comprising:
preparing a substrate including a cell region and a peripheral region having different active region densities;
forming cell trenches for limiting cell active regions in the cell region so that the cell active regions are formed to be spaced apart by a first width in a first direction and by a second width in a second direction;
forming peripheral trenches for limiting a peripheral active region in the peripheral region;
forming, in the cell trenches, a first insulating layer coming in contact with sidewalls of the cell active regions;
forming a peripheral isolation layer in the peripheral trenches; and
forming a second insulating layer surrounded by the first insulating layer and a third insulating layer surrounded by the second insulating layer at centers between the cell active regions spaced apart by the second width.

16. The method of claim 15, wherein the first insulating layer continuously extends in the first and second directions, and
a thickness of the first insulating layer is equal to or greater than half of the first width and less than half of the second width.

17. The method of claim 16, wherein a sum of the thickness of the first insulating layer and thicknesses of the second and the third insulating layers is equal to or greater than half of the first width.

18. The method of claim 15, wherein the peripheral isolation layer includes an insulating layer contacting a sidewall of the peripheral active region and having a lesser thickness than the first insulating layer.

19. The method of claim 18, further comprising forming an intermediate insulating layer on the insulating layer.

20. The method of claim 19, wherein a sum of the thickness of the insulating layer and a thickness of the intermediate insulating layer is less than half of a width of the peripheral trenches.
